(19) United States
(12) Patent Application Publication
(10) Pub. No.: US 2013/0118793 A1
(43) Pub. Date: May 16, 2013

(54) METHOD FOR FILLING THROUGH HOLE OF SUBSTRATE WITH METAL AND SUBSTRATE

(71) Applicants: Takayuki Teshima, Yokohama-shi (JP); Yutaka Setomoto, Tokyo (JP)

(72) Inventors: Takayuki Teshima, Yokohama-shi (JP); Yutaka Setomoto, Tokyo (JP)

(73) Assignee: CANON KABUSHIKI KAISHA, Tokyo (JP)

(21) Appl. No.: 13/811,238

(22) PCT Filed: Jul. 4, 2011
(86) PCT No.: PCT/JP2011/003811

§ 371 Date: Jan. 18, 2013

(30) Foreign Application Priority Data
Jul. 22, 2010 (JP) 2010-165307

(51) Int. Cl. H05K 3/10; H05K 1/11

(52) U.S. Cl. CPC H05K 3/107; H05K 1/115
USPC 174/264; 216/18; 174/266

(57) ABSTRACT

The present invention relates to a method for filling a through hole of a substrate with a metal. The method includes a step of preparing a bonded substrate including a first substrate having conductivity in at least a surface thereof and a second substrate having a through hole, both substrates being bonded to each other through a nonionic surfactant; a step of exposing, in the bonded surface of the bonded substrate, the conductive surface of the first substrate, which is positioned at the bottom of the through hole, by removing the nonionic surfactant positioned at the bottom of the through hole of the second substrate; and a step of filling the through hole with a metal by applying an electric field to the conductive surface of the first substrate.

### TECHNICAL FIELD

The present invention relates to a method for filling through holes of a substrate with a metal and to a substrate.

### BACKGROUND ART

Systems such as integrated circuits, for example, LSI (Large Scale Integrated Circuit), are demanded to be improved in speed and function. In order to further increase the speed and function of these systems such as integrated circuits, a chip mounting technique using a three-dimensional structure is required. Therefore, substrate through electrodes capable of electrically connecting chips with the shortest distance have been used. The substrate through electrodes are formed by forming holes (through holes) passing through a substrate, and then filling the through holes with a metal so that substrates laminated on and below the substrate are electrically connected to each other thorough the metal. A method for filling the through holes with a metal generally includes filling with a plated layer formed by electroplating. After the through holes are filled with a metal by electroplating, planarization is performed by polishing the plated layer projecting from the through holes. The substrate provided with the through holes used is generally a silicon substrate and has an insulating layer, such as a thermally oxidized layer, provided on a surface after the through holes are formed by etching. Therefore, in this state, electroplating is difficult to perform because of the absence of a conductive layer serving as a seed electrode for electroplating.

NPL 1 discloses, as a method for providing a seed electrode, a method of forming a seed electrode on glass, coating the glass with a photoresist, disposing a substrate provided with through holes on the photoresist, and bonding the substrate to the glass through the photoresist serving as an adhesive layer. In this method, in order to expose the seed electrode below the through holes, the photoresist on the seed electrode is removed by dry etching from the surface opposite to the bonded surface. This method is effective for through holes having a large opening area and a small aspect ratio, but the removal of the photoresist is expected to become more difficult as the opening area decreases and the aspect ratio increases. In addition, after plating, the photoresist is separated from the glass, on which the seed electrode has been formed, by dissolving the photoresist in acetone. This is effective for a substrate with a small area, but the distance from a periphery to a center of a substrate increases as the area of the substrate increases for providing many chips. Therefore, a long time is required for penetrating acetone into the space between the seed electrode and the substrate having the through holes provided therein from the periphery of the substrate, and this operation is not necessarily easy to perform.

PTL 1 discloses a method including bonding a film resist to one of the surfaces of a substrate in which through holes are provided, and then patterning the film resist to form an adhesive layer. In this method, a palladium-containing resin layer is formed on a film-shaped resin layer. Further, an electroless nickel plated layer and copper plated layer are deposited in order on the resin layer to prepare a substrate, and the resultant substrate is bonded to the substrate having the patterned film resist serving as the adhesive layer, the film resist being formed on the through holes. Then, the insides of the through holes are plated using the copper plated layer as a seed electrode, and then the palladium-containing resin layer is separated at the interface with the electroless nickel plated layer.

### CITATION LIST

### Patent Literature

### PTL 1: Japanese Patent Laid-Open No. 2006-54307

### Non Patent Literature

### NPL 1: The 14th International Conference on Micro Electro Mechanical Systems (2001)

### SUMMARY OF INVENTION

### Technical Problem

However, the film to which the seed electrode is provided is multilayered, thereby complicating the process. In addition, as the substrate in which the through holes are formed increases in area and decreases in thickness, separation of the substrate after plating may cause cracking or breakage, resulting in demand for further improvement.

The present invention provides a method including a step of preparing a bonded substrate including a first substrate having conductivity in at least a surface thereof and a second substrate having through holes, both substrates being bonded to each other through a nonionic surfactant; a step of exposing, in the bonded surface of the bonded substrate, the conductive surface of the first substrate, which is positioned at the bottoms of the through holes, by removing the nonionic surfactant positioned at the bottoms of the through holes of the second substrate, and a step of filling the through holes with a metal by applying an electric field to the conductive surface of the first substrate.

### Advantageous Effects of Invention

According to the present invention, a conductive layer for filling through holes provided in a substrate with a plated layer can be easily provided. In addition, since then adhesive layer is composed of a surfactant, the conductive layer is easily wetted with a plating solution, and thus the plated layer is uniformly grown.

### BRIEF DESCRIPTION OF DRAWINGS

FIG. 1A is a schematic sectional view illustrating an outline of a method for filling through holes of a substrate with a metal according to the present invention.

FIG. 1B is a schematic sectional view illustrating an outline of a method for filling through holes of a substrate with a metal according to the present invention.

FIG. 1C is a schematic sectional view illustrating an outline of a method for filling through holes of a substrate with a metal according to the present invention.

FIG. 1D is a schematic sectional view illustrating an outline of a method for filling through holes of a substrate with a metal according to the present invention.

FIG. 1E is a schematic sectional view illustrating an outline of a method for filling through holes of a substrate with a metal according to the present invention.

FIG. 2A is a drawing illustrating Example 1 of the present invention.

FIG. 2B is a drawing illustrating Example 1 of the present invention.

FIG. 2C is a drawing illustrating Example 1 of the present invention.

FIG. 2D is a drawing illustrating Example 1 of the present invention.

FIG. 2E is a drawing illustrating Example 1 of the present invention.

FIG. 2F is a drawing illustrating Example 1 of the present invention.

FIG. 2G is a drawing illustrating Example 1 of the present invention.

FIG. 3 is a drawing illustrating Example 4 of the present invention.

### DESCRIPTION OF EMBODIMENTS

A method for filling through holes of a substrate with a metal according to the present invention includes a step of preparing a bonded substrate including a first substrate having a conductive layer on at least a surface thereof and a second substrate having through holes, both substrates being bonded to each other through a nonionic surfactant. Then, the nonionic surfactant layer below the through holes of the bonded substrate is removed to expose the conductive layer below the through holes. Then, an electric field is applied to the conductive layer, and the through holes are filled with a metal by plating.

The present invention is described in detail below with reference to the drawings.

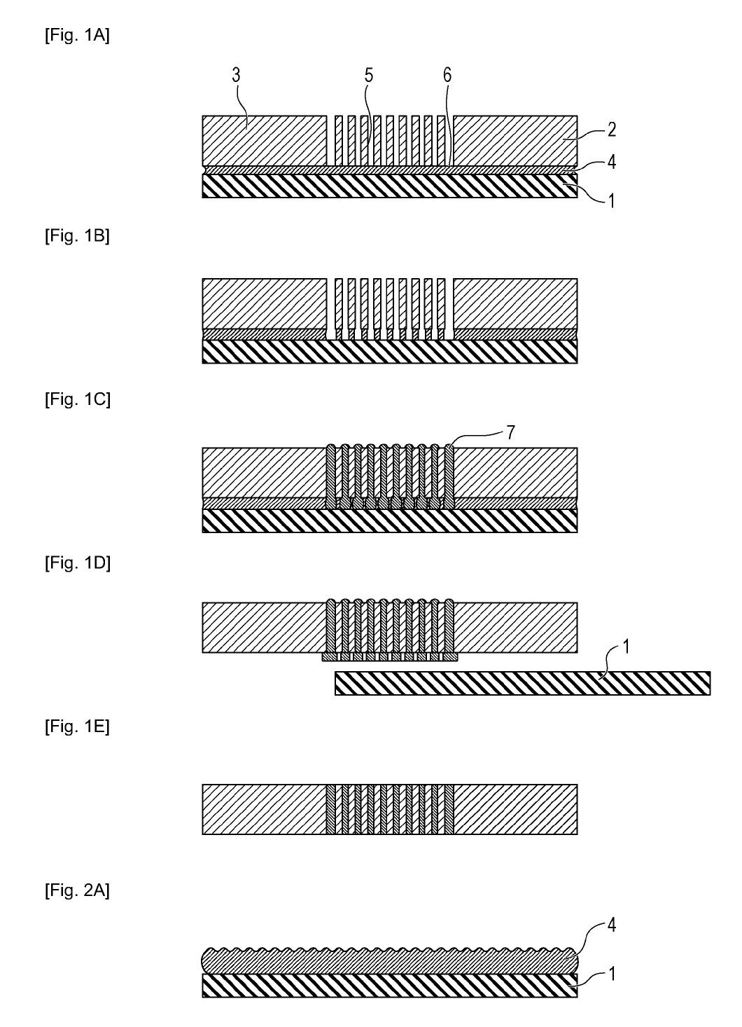

FIGS. 1A to 1E are each a schematic sectional view illustrating an outline of a method for filling through holes of a substrate with a metal according to the present invention.

In the present invention, as shown in FIG. 1A, a bonded substrate 3 including a first substrate 1 having a conductive layer on at least a surface thereof and a second substrate 2 having through holes provided therein is prepared, the first substrate 1 and the second substrate 2 being bonded to each other with a nonionic surfactant 4 provided therebetween.

As the first substrate 1, an insulating substrate on which a metal layer is deposited, and a conductive substrate can be used. As a material for the insulating substrate, inorganic materials such as silicon, glass, and quartz, and organic resin materials such as acryl, polyethylene terephthalate, vinyl chloride, polypropylene, and polycarbonate can be used. Among these materials, materials having heat resistance to the melting point of the nonionic surfactant used can be used. In addition, materials having resistance to the plating solution used are selected. As a material having a conductive surface, a metallic material can be used. When a metallic material is used, the above-described step of depositing a metal film can be omitted. As the metallic material, stainless steel, Hastelloy (trade name), nickel, titanium, platinum, etc. can be used. In this case, materials having resistance to the plating solution used are selected.

As the nonionic surfactant which can be used in the present invention, a surfactant with a hydrophilic portion which is not ionized can be used. Specific examples thereof include polyoxyethylene alkyl ethers, polyethylene glycol, polyvinyl alcohol, sorbitan fatty acid esters, monoglycerin alkyl ethers, and the like. In the present invention the nonionic surfactant is not limited to these as long as it has certain bonding strength and predetermined melting point.

The nonionic surfactant is selected from those having a melting point equal to or higher than the plating temperature. With respect to the melting point, the nonionic surfactant is appropriately selected in view of the molecular weight and molecular chain length. With respect to the water solubility of the nonionic surfactant, the nonionic surfactant having desired HLB (Hydrophile-Lipophile Balance) is appropriately selected in view of a balance between a hydrophilic group and a hydrophobic group. The HLB represents the degree of affinity of the surfactant for water and oil (water-insoluble organic compound).

In the present invention, the nonionic surfactant 6 positioned at the bottoms (the portion bonded to the first substrate) of the through holes of the bonded substrate 3 is removed to expose the conductive surface at the bottoms of the through holes (FIG. 1B). As a result, the conductive surface is exposed at the bottoms of the through holes of the bonded substrate 3 and can be brought into contact with the plating solution. The nonionic surfactant layer 6 at the bottoms of the through holes can be removed by dry etching, UV ozone ashing, or oxygen plasma ashing.

In the present invention, the nonionic surfactant layer 4 at the bottoms of the through holes of the second substrate 2 can also be removed by dissolving in a solvent which can dissolve the nonionic surfactant. Since the solvent has a higher rate of penetration from the through holes than that of penetration from the periphery of the bonded portion (the bonded portion between the first substrate and the second substrate) of the bonded substrate, the nonionic surfactant layer at the bottoms of the through holes can be removed while the bonded state of the bonded substrate is maintained. Examples of the solvent which dissolves the nonionic surfactant include nonprotonic organic solvents such as dimethyl sulfoxide, dimethyl imidazolidinone, sulfolane, N-methyl-2-pyrrolidone, dimethylformamide, acetonitrile, acetone, dioxane, tetramethyl urea, hexamethylphosphoramide, hexamethylphosphortriamide, pyridine, propionitrile, butanone, cyclohexanone, cyclopentanone, tetrahydrofuran, tetrahydropyran, ethylene glycol diacetate, gamma-butyrolactone, and the like. Theses solvents can be used alone or in combination of two or more. Examples of protonic organic solvents include water, methanol, ethanol, isopropyl alcohol, butanol, cyclohexanol, and the like. When the nonionic surfactant is removed by dissolving, an expensive vacuum apparatus for dry etching need not be used.

In the present invention, the through holes of the substrate are filled with a metal by growing the plated layer 7 from the conductive layer below the through holes 5 of the bonded substrate 3 (FIG. 1C). By growing the plated layer 7 from the bottoms of the through holes, the through holes can be filled with a metal without producing voids in the plated layer 7.

As a material of the plated layer 7, copper, nickel, chromium, tin, iron, cobalt, zinc, bismuth, and the like, and alloys thereof can be used.

In the present invention, after the through holes are filled with the plated layer 7, the substrate is heated to a temperature equal to or higher than the melting point of the nonionic surfactant. This causes phase transition of the nonionic surfactant 4 from a solid to a liquid. The phase transition to a liquid produces mobility, and adhesion holding power is lost, thereby facilitating separation of the first substrate 1 from the bonded substrate 3 (FIG. 1D). Therefore, even when the second substrate 2 is increased in area and decreased in thickness, cracking and breakage can be avoided. Also, the separation may be performed in a solvent that can dissolve the nonionic surfactant and that is heated to a temperature equal to or higher than the melting point of the nonionic surfactant. In this case, the nonionic surfactant is changed to a liquid and is easily removed from a gap due to being dissolved in the solvent capable of dissolution.

In the present invention, it is desired to planarize, by polishing, the plated layer 7 projecting from the through holes 5 of the second substrate 2 which is separated from the bonded substrate 3 after plating (FIG. 1E). As a polishing method, mechanical polishing may be used, but chemical mechanical polishing (CMP), elecropolishing (EP), or electrochemical buffing (ECB) may be used in order to improve the polishing rate of a material which is hard to polish.

In the present invention, the bonded substrate 3 including the first substrate 1 and the second substrate 2 which are bonded to each other through the nonionic surfactant 4 can be prepared as follows.

A substrate having a layer of the nonionic surfactant 4 formed on the first substrate 1 is prepared. The layer of the nonionic surfactant 4 can be formed by a method of spin coating, dipping, or spray-coating using a solution of the nonionic surfactant 4, or coating by vacuum deposition or melting. However, the method is not limited to these.

Then, the second substrate 2 is disposed on the first substrate 1, followed by heating to a temperature higher than the melting point of the nonionic surfactant. Heating the nonionic surfactant to a temperature equal to or higher than the melting point thereof causes phase transition from a solid phase to a liquid phase. The transition to a liquid causes the first substrate 1 and the second substrate 2 to attract to each other and adhere to each other (bonded) due to the surface tension of the liquid nonionic surfactant 4. Since the nonionic surfactant 4 is amphipathic and has both a hydrophilic group and a hydrophobic group, the first substrate 1 and the second substrate 2 easily adhere to each other regardless of whether one of the two substrates is hydrophobic or hydrophilic.

Then, the substrates are cooled to a temperature lower than the melting point of the nonionic surfactant 4. This causes phase transition of the nonionic surfactant 4 from a liquid phase to a solid phase. Consequently, the nonionic surfactant 4 functions as a binder layer between the first substrate 1 and the second substrate 2, forming the bonded substrate 3 holding both substrates.

In the present invention, after the plated layer projecting from the through holes of the second substrate 2 is planarized by polishing, a though hole can be formed between some of the adjacent plated layers. In addition, an electron beam control device can be formed using the substrate.

Although the present invention is described in further detail below by giving examples, the present invention is not limited to the description of the examples.

### EXAMPLES

### Example 1

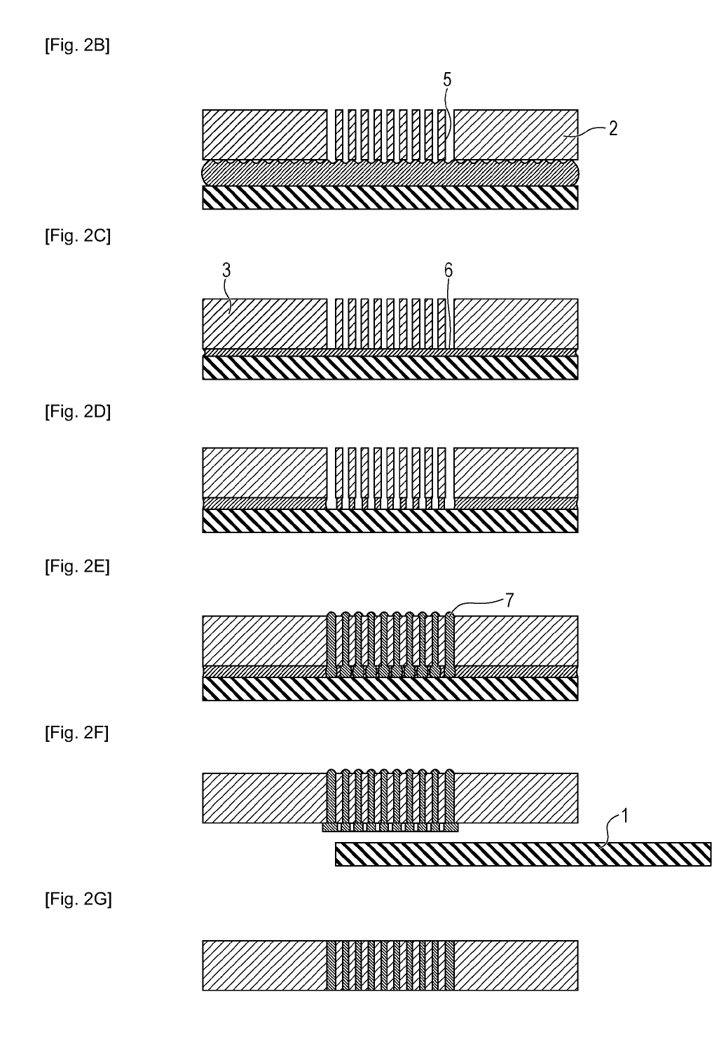

This example is described using FIGS. 2A to 2G. In this example, a bonded substrate 3 was prepared as follows. A stainless film having a diameter of 100 mm and a thickness of 0.1 mm was prepared as a first substrate 1 which was a substrate having a conductive layer. Polyoxyethylene lauryl ether (melting point: 34 degrees Celsius) was used as a nonionic surfactant 4 and dissolved in a mixed solvent of cyclopentanone and acetone at a weight ratio of 3:1 to prepare a 10 wt % polyoxyethylene lauryl ether solution. The resultant solution was applied to the stainless film by spin coating and allowed to stand at room temperature for 15 minutes. As a result, a solid of polyoxyethylene lauryl ether was deposited on the stainless film to form a layer of the nonionic surfactant 4 (FIG. 2A).

As a second substrate 2, a 4-inch wafer having a thickness of 200 micrometers was used, in which through holes were provided in a pair pattern of rectangles having a long side of 60 micrometers and a short side of 15 micrometers and being arranged at a distance of 25 micrometers, the pattern having a (32*32) matrix where 32 rectangle pairs were arranged at a pitch of 160 micrometers in each of the longitudinal and lateral directions. The silicon wafer had a thermally oxidized film formed to a thickness of 1 micrometer on a surface thereof and thus had an insulating surface.

As shown in FIG. 2B, the second substrate 2 was superposed on the layer of the nonionic surfactant 4 of the first substrate 1, and then placed on a hot plate heated to 70 degrees Celsius. Thus, the polyoxyethylene lauryl ether was melted to bond together the first substrate 1 and the second substrate 2 through the melted polyoxyethylene lauryl ether. Then, cooling to room temperature changed the polyoxyethylene lauryl ether to a solid, and thus the first substrate 1 and the second substrate 2 were strongly bonded to each other and used as the bonded substrate 3 (FIG. 2C). In this case, the substrate having the insulating surface and the though holes and the substrate having conductivity can be easily adhered (bonded) to each other. Therefore, a conductive layer serving as a seed electrode for plating can be imparted.

When the bonded substrate 3 was immersed in ion exchange water contained in a beaker for 3 minutes, elusion of the polyoxyethylene lauryl ether from the through holes 5 was observed. Therefore, the polyoxyethylene lauryl ether serving as the nonionic surfactant at the bottoms (the portion bonded to the first substrate) of the through holes of the bonded substrate 3 can be removed, thereby exposing the conductive surface at the bottoms of the through holes. Since the nonionic surfactant can be dissolved with water, the conductive layer below the through holes can be easily exposed without using a dry etching or exposure device which uses an expensive device such as a vacuum device (FIG. 2D). Therefore, the nonionic surfactant below the through holes can be removed by using a solvent which can dissolve the nonionic surfactant.

Then, the bonded substrate 3 was immersed in a copper sulfate plating solution, and an electric field was applied to the conductive surface at room temperature, so that the through holes 5 were filled with the copper plated layer 7 by supplying a current of 48 mA through the stainless film for 10 hours until the plated layer 7 projected from the through holes 5 (FIG. 2E). In this plating, the electrode area was 2.4 cm², and the current density was 2 A/dm² (2 A/square decimeters). A phosphorus-containing copper plate was used as an anode for copper sulfate plating. The copper sulfate plating solution used was prepared using the following composition:
Copper sulfate pentahydrate 200 (g/L)
98% conc. sulfuric acid 14 (mL/L)
35% hydrochloric acid 0.09 (mL/L)
Cu-Brite VFII-A (manufactured by Ebara Udylite Co., Ltd.) 20 (mL/L)
Cu-Brite VFII-B (manufactured by Ebara Udylite Co., Ltd.) 1 (mL/L)
   The adhesive layer composed of a surfactant has the effect of promoting the occurrence of a uniform plated layer due to high wettability of the conductive layer with the plating solution. In addition, the substrate having conductivity can be easily separated after plating.

After the completion of plating, the bonded substrate was washed with water and then dried with nitrogen blowing. The substrate was placed on a hot plate heated to 80 degrees Celsius so that the surface of the substrate on which the plated layer projected faced downward and was in contact with the loading surface of the hot plate, thereby melting the polyoxyethylene lauryl ether. The stainless film of the first substrate 1 was picked up with a pincette and only the stainless film was separated by moving it in parallel with the substrate surface (FIG. 2F). Both surfaces of the second substrate 2 on which the plated layer 7 projected were polished by chemical mechanical polishing (CMP) so that the projecting plate layer 7 was planarized to the same height as the surface of the second substrate 2 (FIG. 2G). The planarized surface can be used for a connection pad for an electrode so as to permit electric connection to a substrate disposed on the surface of the substrate. In addition, the need for making the amount of projection of the plated layer constant is eliminated by planarization, and thus a process margin for plating conditions can be increased.

As a result of optical microscope observation of both surfaces of the second substrate 2 provided with the through holes, the through holes were completely filled with the plated layer 7. In addition, observation of a section showed no void in the plated layer 7, and thus it was confirmed that the through holes 5 are filled with the copper plated layer 7.

### Comparative Example 1

In this comparative example, a positive resist was used as an adhesive layer in place of the nonionic surfactant.

A stainless film having a diameter of 100 mm and a thickness of 0.1 mm was prepared. Positive resist AZ1500 (manufactured by AZ Materials Co. Ltd.) was applied to the stainless film by spin coating and pre-baked at 100 degrees Celsius for 1 minute.

The same substrate provided with through holes as in Example 1 was superposed on the stainless film, and placed on a hot plate heated to 100 degrees Celsius, thereby bonding them by heating. Then, the positive resist below the through holes was removed with a developer after exposure from above the through holes. Then, post baking was performed at 120 degrees Celsius for 10 minutes. Further, the positive resist remaining below the through holes was removed by a dry etching apparatus using oxygen plasma. Next, plating was performed until a plated layer projected from the through holes by the same method as in Example 1.

After the completion of plating, the substrate was washed with water and dried by nitrogen blowing. The substrate was immersed in acetone for 24 hours. However, the stainless film was strongly bonded to the substrate and could not be separated. Further, the substrate was immersed in N-methyl-2-pyrrolidone heated to 60 degrees Celsius for 2 hours, but the stainless film could not be separated. Further, a pincette was inserted between the substrate provided with the through holes and the stainless film, and the stainless film was separated. However, the substrate provided with the through holes was cracked. As a result of observation of the cracked surface, it was found that acetone and N-methyl-2-pyrrolidone which are solvents for dissolving the positive resist do not enter a space due to the residual positive resist, thereby failing to remove the stainless film.

### Example 2

In this example, a bonded substrate 3 was prepared as follows. Titanium and copper were deposited in order to thicknesses of 50 angstroms and 1000 angstroms, respectively, on a polyethylene terephthalate film having a diameter of 100 mm and a thickness of 0.2 mm by electron beam deposition, forming a substrate with a conductive layer formed on a surface thereof. The substrate was used as a first substrate 1 having conductivity in a surface thereof.

Polyoxyethylene lauryl ether (melting point: 34 degrees Celsius) used as a nonionic surfactant was dissolved in a mixed solvent of cyclopentanone and acetone at a weight ratio of 3:1 to prepare a 10 wt % polyoxyethylene lauryl ether solution. The resultant solution was applied to the polyethylene terephthalate film by spin coating and then allowed to stand at room temperature for 15 minutes, and consequently a solid of polyoxyethylene lauryl ether was deposited on the polyethylene terephthalate film, forming a layer of the nonionic surfactant 4. The second substrate 2 used was the same as that of Example 1.

The second substrate 2 was superposed on the layer of the nonionic surfactant 4 of the first substrate 1 and placed on a hot plate heated to 60 degrees Celsius. Therefore, the polyoxyethylene lauryl ether was melted by heating to bond together the first substrate 1 and the second substrate 2. Then, the substrates were cooled to room temperature to convert the polyoxyethylene lauryl ether to a solid, and thus the first substrate 1 and the second substrate 2 provided with through holes were strongly bonded to each other and used as the bonded substrate 3.

The bonded substrate 3 was immersed in ion exchange water contained in a beaker. As a result of observation of the through holes 5, elusion of polyoxyethylene lauryl ether from the through holes 5 was observed.

Then, the bonded substrate 3 was immersed in a copper sulfate plating solution, and an electric field was applied to the conductive layer at room temperature. In addition, a current of 60 mA was supplied for 9 hours 30 minutes so that the through holes 5 were filled with a copper plated layer 7 by plating until the end of the plated layer projected from the through holes 5. In this plating, the electrode area was 2.4 cm², and the current density was 2 A/dm². A phosphorus-containing copper plate was used as an anode for copper sulfate plating. The copper sulfate plating solution used was prepared using the following composition:
Copper sulfate pentahydrate 200 (g/L)
98% conc. sulfuric acid 14 (mL/L)
35% hydrochloric acid 0.09 (mL/L)
Cu-Brite VFII-A (manufactured by Ebara Udylite Co., Ltd.) 20 (mL/L)
Cu-Brite VFII-B (manufactured by Ebara Udylite Co., Ltd.) 1 (mL/L)

After the completion of plating, the substrate was washed with water and dried by nitrogen blowing. The substrate was immersed in hot water contained in a beaker and was shaken. The polyoxyethylene lauryl ether of an adhesive layer was converted to a liquid by the hot water of a temperature higher than the melting point thereof, and was dissolved in the hot water serving as a dissolving solvent. Therefore, the polyethylene terephthalate film was separated. Like in Example 1, it was confirmed that the through holes 5 are filled with the copper plated layer 7.

### Example 3

In this example, a bonded substrate 3 was prepared as follows. A stainless film having a diameter of 100 mm and a thickness of 0.1 mm was used as a first substrate 1 having conductivity. Polyethylene glycol 20000 (melting point: 63 degrees Celsius) used as a nonionic surfactant 4 was dissolved in a mixed solvent of cyclopentanone and acetone at a weight ratio of 3:1 to prepare a 10 wt % polyethylene glycol 20000 solution. The resultant solution was applied to the stainless film by spin coating and then allowed to stand at room temperature for 15 minutes. Consequently, a solid of polyethylene glycol 20000 was deposited on the stainless film, forming a layer of the nonionic surfactant 4.

The second substrate 2 used was the same as that of Example 1.

The second substrate 2 was superposed on the layer of the nonionic surfactant 4 of the first substrate 1 and placed on a hot plate heated to 85 degrees Celsius. Therefore, the polyethylene glycol 20000 was melted to bond together the first substrate 1 and the second substrate 2. Then, the substrates were cooled to room temperature to convert the polyethylene glycol 20000 to a solid, and thus the first substrate 1 and the second substrate 2 were strongly bonded to each other and used as the bonded substrate 3.

The bonded substrate 3 was immersed in ion exchange water contained in a beaker for 3 minutes. As a result of observation of the through holes 5, elusion of polyethylene glycol 20000 from the through holes 5 was observed.

Then, the bonded substrate 3 was immersed in a nickel sulfamate plating solution, and an electric field was applied to the stainless film at a plating solution temperature of 50 degrees Celsius. In addition, a current of 40 mA was supplied for 10 hours so that the through holes 5 were filled with a nickel plated layer 7 by plating until the end of the plated layer projected from the through holes 5. In this plating, the electrode area was 2.4 cm², and the current density was 2 A/dm². A SK nickel plate was used as an anode for nickel sulfamate plating. The nickel sulfamate plating solution used was prepared using the following composition:
Nickel sulfamate hexahydrate 450 (g/L)
Nickel chloride hexahydrate 14 (g/L)
Boric acid 30 (g/L)
Saccharin sodium 1.5 (g/L)
Butynediol 0.15 (g/L)

After the completion of plating, the substrate was washed with water and dried by nitrogen blowing. The substrate was placed on a hot plate heated to 100 degrees Celsius so that the surface of the substrate on which the plated layer projected faced downward, thereby melting the polyethylene glycol 20000 by heating. The stainless film was picked up with a pincette and only the stainless film was separated by moving it in parallel with the substrate surface. As a result of optical microscope observation of both surfaces of the second substrate 2 provided with the through holes, the through holes were completely filled with the plated layer 7. In addition, observation of a section showed no void in the plated layer 7, and thus it was confirmed that the through holes 5 are filled with the nickel plated layer 7.

### Example 4

In this example, a blanking array 10 which can be used in an electron beam control device is formed as follows. The substrate including the plated layer 7 planarized by polishing in Example 1 is used. A photoresist is patterned so as to exposure only the spaces in a pair pattern of rectangles arranged at a distance of 25 micrometers. The exposed portions are etched in the thickness direction of the substrate by ICP-RIE (Inductive Coupled Plasma-Reactive Ion Etching) deep etching to form through holes. A substrate having wiring which is formed to permit current supply to the planarized plated layer 7 is bonded by bump bonding.

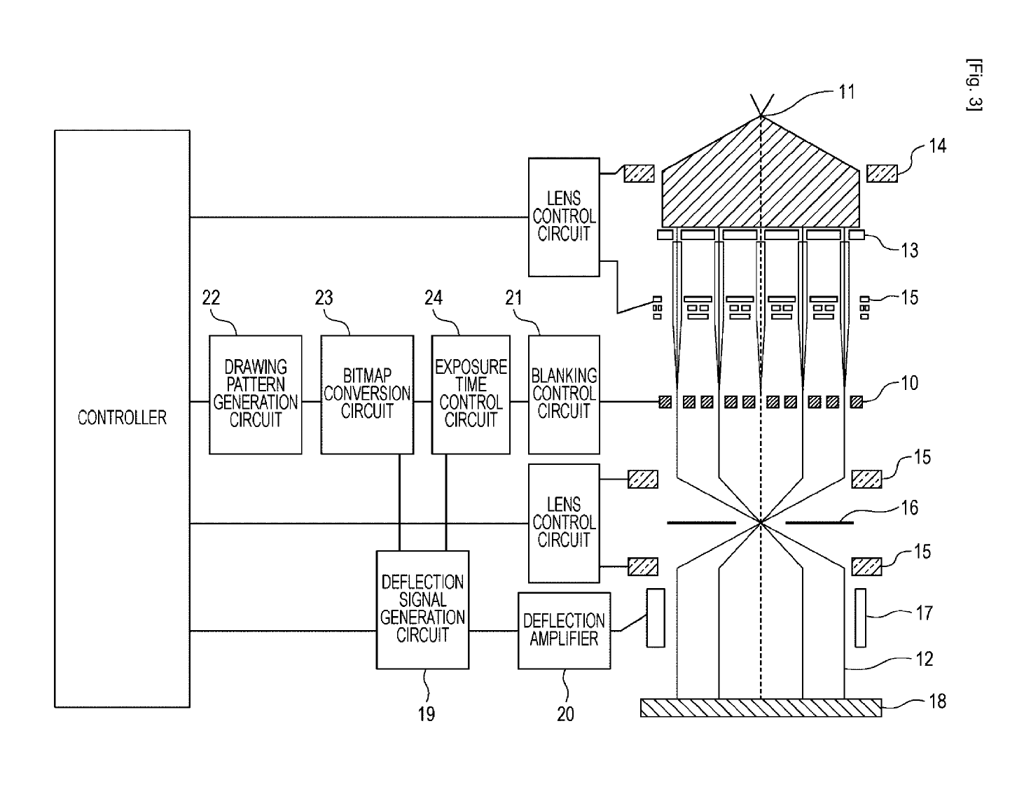

An electron beam control device of this example is described with reference to FIG. 3. An electron beam 12 emitted radially from an electron source 11 (charged particle source) is shaped to an areal beam having a desired size by a collimator lens 14 and then incident on a mask 13 substantially perpendicularly. The mask 13 has a plurality of patterns. The electron beam 12 formed through the mask 13 is converged to a blanking array 10 through a lens 15. The blanking array 10 is a deflection plate array and capable of defecting each beam. The beam deflected by the blanking array 10 is cut off by a blanking diaphragm 16, while the beam not deflected by the blanking array 10 is converged through a lens 15, passes through the blanking diaphragm 16, is converged through a lens 15, and applied to a sample 18 after an irradiation position on the sample is controlled by a deflector 17. The deflector 17 performs raster scanning so that the beam is applied to a desired position according to the scan timing of the deflector 17 and the operation timing of the blanking array 10. Each of the lenses is controlled by a lens control circuit, and the deflector 17 is controlled by transmitting a raster deflection signal, which is generated from a deflection signal generation circuit 19, to a deflection amplifier 20. The blanking array 10 is controlled by a blanking control circuit 21 which is controlled by a blanking signal generated by a drawing pattern generation circuit 22, a bitmap conversion circuit 23, and an exposure time control circuit 24.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-165307, filed Jul. 22, 2010, which is hereby incorporated by reference herein in its entirety.

1. A method for filling a through hole of a substrate with a metal, the method comprising:
a step of preparing a bonded substrate including a first substrate having conductivity in at least a surface thereof and a second substrate having a through hole, both substrates being bonded to each other through a nonionic surfactant;
a step of exposing, in the bonded surface of the bonded substrate, the conductive surface of the first substrate, which is positioned at the bottom of the through hole, by removing the nonionic surfactant positioned at the bottom of the through hole of the second substrate; and
a step of filling the through hole with a metal by applying an electric field to the conductive surface of the first substrate.

2. The method according to claim 1, further comprising, after filling the through hole with the metal, a step of heating the nonionic surfactant to a temperature equal to or higher than the melting point thereof and separating between the first substrate and the second substrate.

3. The method according to claim 1, further comprising, after the step of separating between the first substrate and the second substrate, a step of planarizing the second substrate by polishing the metal projecting from the through hole.

4. The method according to claim 1, wherein the bonded substrate is formed by:
a step of preparing the first substrate and the second substrate, a nonionic surfactant layer being formed on at least one of the surfaces of the first substrate or the second substrate;
a step of disposing the first substrate and the second substrate so that both substrates are bonded through the nonionic surfactant layer, and heating the substrates to a temperature equal to or higher than the melting point of the nonionic surfactant; and
a step of, after melting the nonionic surfactant layer, solidifying the nonionic surfactant by cooling to a temperature equal to or lower than the melting point of the nonionic surfactant.

5. The method according to claim 1, wherein the step of removing the nonionic surfactant from the bottom of the through hole of the bonded substrate is performed by dissolving the nonionic surfactant in a solvent capable of dissolution.

6. A bonded substrate comprising:
a first substrate having conductivity in at least a surface thereof; and
a second substrate having a through hole, the first substrate and the second substrate being bonded to each other through a nonionic surfactant layer.

7. The substrate according to claim 6, wherein the through hole is filled with a metal.
